(19) United States
(12) Patent Application Publication
(10) Pub. No.: US 2011/0121359 A1
(43) Pub. Date: May 26, 2011

(54) Multi-Layer Reconfigurable Switches

(76) Inventors: Jianhua Yang, Palo Alto, CA (US); Julien Borghetti, Palo Alto, CA (US); Duncan Stewart, Palo Alto, CA (US); R. Stanley Williams, Palo Alto, CA (US)

(21) Appl. No.: 13/056,101

(22) PCT Filed: Jul. 31, 2008
(86) PCT No.: PCT/US08/09246

§ 371 Date: Jan. 26, 2011

(51) Int. Cl. H01L 29/86; B82Y 99/00

(52) U.S. Cl. 257/109; 977/762; 257/E29.325

(57) ABSTRACT

Embodiments of the present invention are directed to reconfigurable two-terminal electronic switch devices (100) comprising a compound (102) sandwiched between two electrodes (104,106). These devices are configured so that the two electrode/compound interface regions can be either rectifying or conductive, depending on the concentration of dopants at the respective interface, which provides four different device operating characteristics. By forcing charged dopants into or out of the interface regions with an applied electric field pulse, a circuit element can be switched from one type of stable operation to another in at least three different ways. A family of devices built to express these properties display behaviors that provide new opportunities for nanoscale electronic devices.

### TECHNICAL FIELD

Embodiments of the present invention are related to nanoscale electronic devices, and, in particular, to re-configurable diode switches that can be implemented in crossbar arrays.

### BACKGROUND

Significant research and development efforts are currently directed towards designing and manufacturing nanoscale electronic devices, such as nanoscale memories. Nanoscale electronics promise a number of advantages over microscale, photolithography-based electronics, including significantly reduced features sizes and the potential for self-assembly and for other relatively inexpensive, non-photolithography-based fabrication methods. However, the design and manufacture of nanoscale electronic devices present many new problems need to be addressed before large-scale commercial production of nanoscale electronic devices and incorporation of nanoscale electronic devices into microscale and larger-scale systems, devices, and products.

Studies of switching in nanometer-scale crossed-wire devices have previously reported that these devices could be reversibly switched and had an “on-to-off” conductance ratio of ˜10³. These devices have been used to construct crossbar circuits and provide a promising route for the creation of ultra-high density nonvolatile memory. A series connection of cross-wire switches that can be used to fabricate a latch has also been demonstrated, such a latch is an important component for logic circuits and for communication between logic and memory. New logic families that can be constructed entirely from crossbar arrays of switches or as hybrid structures composed of switches and transistors have been described. These new logic families have the potential to dramatically increase the computing efficiency of CMOS circuits, thereby enabling performance improvements of orders of magnitude without having to shrink transistors, or to even replace CMOS for some applications if necessary. However, it is desired to improve the performance of the devices that are presently fabricated.

### SUMMARY

Various embodiments of the present invention are direct to nanoscale, reconfigurable, two-terminal electronic switches. In one embodiment, an electronic switch includes a first electrode, a second electrode, and an active region disposed between the first electrode and the second electrode and including at least one dopant. The switch can be re-configured to operate as a forward rectifier, a reverse rectifier, a shunted rectifier, or a head-to-head rectifier by positioning the dopant within the active region in order to control the flow of charge carriers through the switch.

### BRIEF DESCRIPTION OF THE DRAWINGS

FIG. 1A shows a two-terminal switch configured in accordance with embodiments of the present invention.

FIG. 1B shows profiles of tunneling barriers associated with four rectifiers configured in accordance with embodiments of the present invention.

FIG. 2 shows plots of current-versus-voltage curves associated with the four rectifiers shown in FIG. 1B and three modes of switching between pairs of the rectifiers in accordance with embodiments of the present invention.

FIG. 3 shows an isometric view of a nanowire crossbar array configured in accordance with embodiments of the present invention.

FIG. 4 shows an isometric view of a nanowire crossbar revealing switches located at intersection of a crossbar configured in accordance with embodiments of the present invention.

FIG. 5A shows an isometric view of four separate switches configured to demonstrate the role oxygen vacancies play in switches in accordance with embodiments of the present invention.

FIG. 5B shows a plot of current-versus-voltage curves associated with switches shown in FIG. 5A in accordance with embodiments of the present invention.

FIG. 6 shows an isometric view of a switch configured in accordance with embodiments of the present invention.

FIGS. 7A-7C shows experimental results obtained from shunting switching a Pt/TiO₂/Pt switch in accordance with embodiments of the present invention.

FIGS. 8A-8C represent experimental results obtained from opening switching a Pt/TiO₂/Pt switch in accordance with embodiments of the present invention.

FIGS. 9A-9C represent experimental results obtained from inverting switching a Pt/TiO₂/Pt switch in accordance with embodiments of the present invention.

### DETAILED DESCRIPTION

Various embodiments of the present invention are directed to nanoscale, two-terminal, electronic switches, which are nonvolatile and combine reconfigurable diode rectifying states with memristive switching. A switch configured in accordance with embodiments of the present invention is composed of an active region sandwiched between two electrodes. The two interfaces between the active region and the electrodes are Schottky contacts. The active region is a diode that can be switched into one of four different rectifying states by applying an electrical field of an appropriate magnitude and polarity across the active region. The electric field changes the Schottky contacts at the interfaces to have Ohmic-like barriers and/or Schottky-like barriers, thus enabling the active region to be configured and the switch to operate as one of the four types of rectifiers: a forward rectifier, a reverse rectifier, a shunted rectifier, and a head-to-head rectifier. The active region remains in a particular rectifying state provided operating voltages applied to the switch do not exceed the magnitude of the electric field used to switch the rectifying state of the active region.

The detailed description is organized as follows. A description of two-terminal electronically actuated switches is provided in a first subsection. A description of switching the rectifying state of the switches is provided in a second subsection. Various materials that can be used to fabricate the switches are provided in a third subsection. Implementing the switches in crossbar arrays is provided in a fourth subsection. Finally, a switch composed of platinum electrodes and a TiO₂ active region is described in a fifth subsection.

### I. A Two-Terminal Electronically Actuated Switch

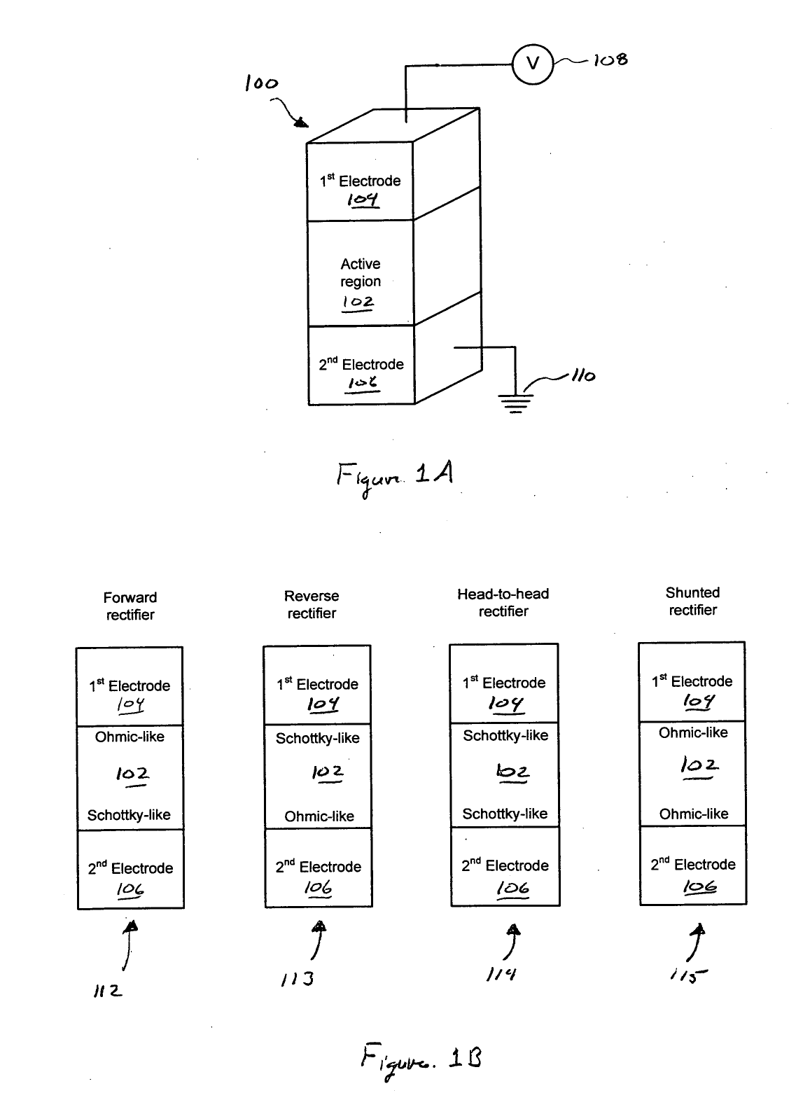

FIG. 1A shows a two-terminal switch 100 configured in accordance with embodiments of the present invention. The switch 100 is composed of three layers: an active region 102 sandwiched between a first electrode 104 and a second electrode 106. The first electrode 104 is connected to a voltage source 108 and the second electrode is connected to a ground 110. The active region 102 is a diode that includes a dopant. Applying an electric field of an appropriate magnitude and polarity changes the position of the dopant. As a result, the active region 102 can be operated as one of the four different types of rectifiers: a forward rectifier, a reverse rectifier, a head-to-head rectifier, and a shunted rectifier.

The active region 102 is composed of a primary active region, or layer, and a secondary active region, or layer. The primary active region comprises a thin film of a material that is electronically semiconducting or nominally electronically insulating and can also be a weakly ionic conductor. The primary active material is capable of transporting and hosting ions that act as dopants to control the flow of electrons through the switch 100. The basic mode of operation is to apply an electrical field of an appropriate magnitude and polarity across the active region 102. When the magnitude of the electrical field, also called a “drift field,” exceeds some threshold for enabling the motion of the dopants in the primary material the dopant can drift into or out of the primary material via ionic transport. The ionic species are specifically chosen from those that act as electrical dopants for the primary material, and thereby change the rectifying state of the primary active material. For example, a rectifier can be changed from low conductivity (i.e, an undoped semiconductor or insulator—switch “off” configuration) to high conductivity (doped to provide a higher conductivity—switch “on” configuration) or from high conductivity to low conductivity (switch “on” to switch “off”). In addition, the primary active material and the dopants are chosen such that the drift of the dopants into or out of the primary active material is possible but not too facile in order to ensure that the active region 102 remains in a particular rectifying state for a reasonable period of time, perhaps for many years at room temperature. This ensures that the active region 102 is nonvolatile. In other words, the active region 102 is memristive (i.e., memory resistive) and holds its rectifying state after the drift field has been removed. Applying a drift field with a large enough magnitude causes both electron current and dopant to drift, whereas applying biases with lower relative voltage magnitudes than the drift field causes negligible dopant drift enabling the switch to hold its rectifying state.

On the other hand, the secondary active material comprises a thin film that is a source of dopants for the primary active material. These dopants may be impurity atoms such as hydrogen or some other cation, such as alkali or transition metals, that act as electron donors for the primary active material. Alternatively, the dopants can be anion vacancies, which in the primary active material are charged and therefore are also electron donors for the lattice. It is also possible to drive the anions into the primary active material, which become electron acceptors or hole donors.

The primary active material can be nanocrystalline, nanoporous, or amorphous. The mobility of the dopants in such nanostructured materials is much higher than in bulk crystalline material, since diffusion can occur through grain boundaries, pores or through local structural imperfections in an amorphous material. Also, because the primary active material film is thin, the amount of time needed for dopants to diffuse into or out of region of the film to substantially change the film's conductivity is relatively rapid. For example, the time needed for a diffusive process varies as the square of the distance covered, so the time to diffuse one nanometer is one-millionth the time to diffuse one micrometer.

The primary active and secondary active materials of the active region 102 are contacted on either side by metal electrodes 104 and 106, or one of the electrodes can be composed of a semiconductor material and the other a metal. When the active region 102 is composed of semiconductor material, the contract between a metal electrode and the active region 102 depletes the active region 102 of free charge carriers. Thus, the active region 102 has a net charge that depends on the identity of the dopant which is positive in the case of electron donors and negative in the case of electron acceptors. The traditional description of electrode/semiconductor Schottky and Ohmic barriers is modified by the fact that the materials are structured at the nanoscale, and so the structural and electronic properties are not averaged over the large distances over which the theory of metal-semiconductor contracts have been developed. Thus, the undoped electrode/active region interfaces electronically resemble Schottky barriers and are called “Schottky-like barriers,” and the doped electrode/semiconductor interfaces electronically resemble Ohmic barriers and are called “Ohmic-like barriers.”

Conduction of electrons through the primary active material is via quantum mechanical tunneling through the Ohmic-like barrier. When the semiconducting material has a low dopant concentration or is essentially intrinsic, the tunneling barrier is a Schottky-like barrier, which is high and wide. Thus, the conductivity through the switching material 102 is low and the device 100 is in the “off” state. When a significant number of dopants have been injected into the semiconductor, the tunneling barrier is an Ohmic-like barrier and the width and perhaps the height of the tunneling barrier are diminished by the potential of the dopants, which results in an increase in the conductivity, and the device 100 is in the “on” state.

Each of the four rectifiers has a different dopant arrangement. When the dopant is located at or near an electrode/active region interface, the interface has an Ohmic-like barrier. Thus, charge carriers can readily tunnel through the Ohmic-like barrier into and out of the active region 102. On the other hand, an undoped portion of the active region 102 at or near an electrode/active region interface has a Schottky-like barrier that is either too high or wide to permit most charge carriers from tunneling through the active region 102. FIG. 1B shows the relative locations of the Ohmic-like and Schottky-like barriers associated with each of the four rectifiers in accordance with embodiments of the present invention. A forward rectifier 112 and a reverse rectifier 113 have Ohmic-like barriers and Schottky-like barriers located at opposite interfaces. A head-to-head rectifier 114 is characterized by having the dopants distributed within the active region 102 leaving Schottky-like barriers at both interfaces. On the other hand, a shunted rectifier 115 is characterized by having dopants located at or near both interfaces creating Ohmic-like barriers at both interfaces.

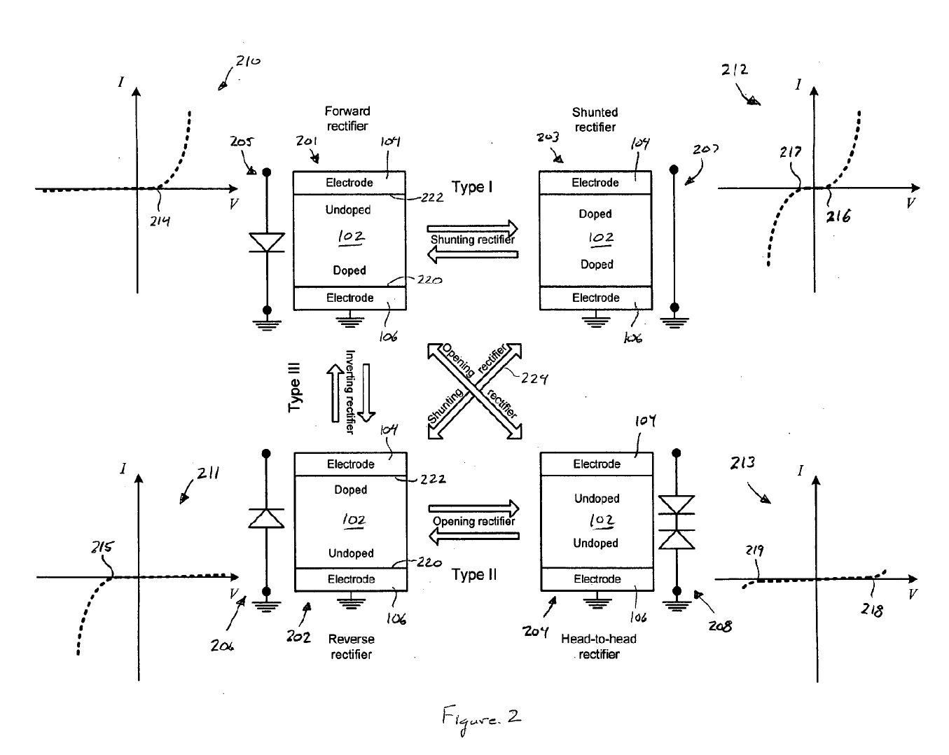

Switching from one rectifier to another can be accomplished by applying an electric field of an appropriate magnitude and polarity across the active region 102. The electric field forces the dopants to drift into or out of the electrode/active region interface regions thus changing the rectifying state of the device 100. For example, as shown in FIG. 1B, an appropriate electric field can be used to force dopants located near the interfaces of the shunted rectifier 115 to move to one of the interfaces thus changing the shunted rectifier 115 into either the forward rectifier 112 or the reverse rectifier 113. The current-versus-voltage (I-V) characteristic curves associated with each of the four rectifiers and switching from one rectifier to another is described in greater detail below with reference to FIG. 2.

The ability of the charged species to diffuse into and out of the primary active material is substantially improved if one of the interfaces connecting the active region 102 to a metal or semiconductor electrode is non-covalently bonded. Such an interface may be caused by a void in the material or it may be the result of an interface that contains a material that does not form covalent bonds with the electrode, the primary active material, or both. This non-covalently bonded interface lowers the activation energy of the atomic rearrangements that are needed for drift of the dopants in the primary active material. This interface is essentially an extremely thin insulator, and adds very little to the total series resistance of the switch.

One potentially useful property of the primary active material is that it can be a weak ionic conductor. The definition of a weak ionic conductor depends on the application for which a switch 100 is designed. The mobility μ_{d} and diffusion constant D for a dopant in a lattice are directly proportional to one another as characterized by the Einstein relation:

D=μ_{d}kT

where k is Boltzmann's constant, and T is absolute temperature. Thus, if the mobility μ_{d} of a dopant in a lattice is high so is the diffusion constant D. In general, it is desired for the active region 102 of the switch 100 to maintain a particular rectifying state for an amount of time that may range from a fraction of a second to years, depending on the application. Thus, it is desired that the diffusion constant D be low enough to ensure a desired level of stability, in order to avoid inadvertently turning the active region 102 from one rectifier to another rectifier via ionized dopant diffusion, rather than by intentionally setting the state of the active region 102 with an appropriate voltage. Therefore, a weakly ionic conductor is one in which the dopant mobility μ_{d} and the diffusion constant D are small enough to ensure the stability or non-volatility of the active region 102 for as long as necessary under the desired conditions. On the other hand, strongly ionic conductors would have relatively larger dopant mobilities and be unstable against diffusion.

### II. Non-volatile Memristive Switching of the Switch

The active region 102 is non-volatile and re-configurable and exhibits diode rectifying states with memristive switching. FIG. 2 shows schematic profiles of the four rectifiers 201-204 of the active region 102 and three modes of switching between pairs of the rectifiers in accordance with embodiments of the present invention. In addition to the four rectifiers 201-204, FIG. 2 includes circuit diagrams 205-208 and I-V characteristic plots 210-213 that are associated with each of the four rectifiers 201-204. As shown in FIG. 2, each of the four rectifiers 201-204 of the switch 100 represents a different profile distribution of dopants, and therefore, has a different associated I-V characteristic represented in each of the plots 210-213. Electrode/active region contacts are typically Ohmic-like in the case of heavy doping, and rectifying or Schottky-like in the case of low doping. Thus, the concentration of dopants at an interface determines the electrical behavior, and therefore, the transport of electrons through the switch 100. In FIG. 2, the four different rectifiers 201-204 are identified as a forward rectifier, a reverse rectifier, a shunted rectifier, and a head-to-head rectifier, respectively. The rectifying state properties of each of these rectifiers depend on the distribution of dopants within the active region 102.

The plots 210-213 of the I-V characteristic curves reveal the response of the switch 100 to different voltage polarities and magnitudes. In particular, plot 210 reveals that when the switch 100 is configured as the forward rectifier 201, current flows from the first electrode 104 to the second electrode for positive polarity voltages exceeding a voltage 214 and resistance is large for negative polarity voltages. Plot 211 reveals that when the switch 100 is configured as the reverse rectifier 202, current flows from the second electrode 106 to the first electrode 104 for negative polarity voltages exceeding a voltage 215 and resistance is large for positive polarity voltages. Plot 212 reveals that when the switch 100 is configured as the shunted rectifier 203, current substantially flows undisturbed through the switch 100 for positive and negative polarity voltages with magnitudes exceeding voltages 216 and 217. Finally, plot 213 reveals that when the switch 100 is configured as a head-to-head rectifier 204, the resistance of the switch 100 is high for positive and negative polarity voltages between voltages 218 and 219. Note that plots 210-213 show only operating voltage ranges. In other words, the magnitudes of voltages applied to the rectifiers 201-204 represented in plots 210-213 are not large enough to change the rectifier to a different rectifier or destroy the switch 100.

The dopants are mobile under an appropriate drift field because the active region 102 may only be a few nanometers thick. The reconfiguration of the dopant profiles due to the drift of dopants under a drift field leads to electrical switching between the four rectifiers. As shown in FIG. 2, shunting is switching between the forward rectifier 201 and the shunted rectifier 203. In this switching, interface 220 is heavily doped and remains Ohmic-like with negligible changes during the electrical biasing. A bias with an appropriate polarity and magnitude on the first electrode 104 attracts a portion of the dopants to the interface 222, switching the device from the forward rectifier 201 to the shunted rectifier 203. A bias with an opposite polarity and approximately the same magnitude switches the shunted rectifier 203 back to the forward rectifier 201. Of course, the switching between the reverse rectifier 202 and the shunted rectifier 203 also belongs to this type of switching, indicated by diagonal arrow 224.

Opening is switching between the reverse rectifier 202 and the head-to-head rectifier 204. In this case, the undoped interface 220 remains unchanged and only the doped interface 222 is switched. The undoped interface contains few dopants and remains rectifying instead of Ohmic-like. A bias of an appropriate polarity and magnitude on the first electrode 104 forces dopants away from the interface 222 and switches the reverse rectifier 202 into the head-to-head rectifier 204, and vice versa. The switching between the forward rectifier 201 and the back-to-back rectifier 204 is also opening.

Inverting between the forward rectifier 201 and the reverse rectifier 202 involves simultaneously applying oppositely polarized biases to the electrodes 104 and 106. For example, switching from the forward rectifier 201 to the reverse rectifier 202 is accomplished by applying oppositely polarized biases to the electrodes 104 and 106 to forces dopants away from the interface 220 and at the same time attracts dopants to the interface 222. Switching from the reverse rectifier 202 to the forward rectifier 201 is accomplished by applying oppositely polarized biases to the electrodes 104 and 106 to force dopants away from the interface 222 and at the same time attract dopants to the interface 220. Therefore, the dopant profile across the active region 102 is essentially inverted and so is the rectifying orientation, resulting in a switching between a reverse rectifier and a forward rectifier.

### III. Active Region Materials

The electrodes 104 and 106 can be composed of platinum, gold, silver, copper, or any other suitable metal, metallic compound (e.g. some perovskites such as BaTiO₃ and Ba₁₋ₓLaₓTiO₃) or semiconductor. The primary and secondary active materials of the active region 102 can be oxides, sulfides, selenides, nitrides, phosphides, arsenides, chlorides, and bromides of the transition and rare earth metals, with or without the alkaline earth metals being present. In addition, there are various alloys of these compounds with each other, which can have a wide range of compositions if they are mutually soluble in each other. In addition, the active region 102 can be composed of mixed compounds, in which there are two or more metal atoms combined with some number of electronegative elements. The dopants can be anion vacancies or different valence elements doped in the active region 102. One combination of materials is a primary active material that is undoped and stoichiometric, and thus a good insulator, combined with a secondary source/sink of the same or related parent material that either contains a large concentration of anion vacancies or other dopants that can drift into the primary material under the application of an appropriate bias.

The active region 102 can be composed of oxides that contain at least one oxygen atom (O) and at least one other element. In particular, the active region 102 can be composed of titania (TiO₂), zirconia (ZrO₂), and hafnia (HfO₂). These materials are compatible with silicon (Si) integrated circuit technology because they do not create doping in the Si. Other embodiments for the active region 102 include alloys of these oxides in pairs or with all three of the elements Ti, Zr, and Hf present. For example, the active region 102 can be composed of TiₓZr_{y}Hf_{z}O₂, where x+y+z=1. Related compounds include titanates, zirconates, and hafnates. For example, titanates includes ATiO₃, where A represents one of the divalent elements strontium (Sr), barium (Ba) calcium (Ca), magnesium (Mg), zinc (Zn), and cadmium (Cd). In general, the active region 102 can be composed of ABO₃, where A represents a divalent element and B represents Ti, Zr, and Hf. The active region 102 can also be composed of alloys of these various compounds, such as CaₐSr_{b}Ba_{c}TiₓZr_{y}Hf_{z}O₃, where a+b+c=1 and x+y+z=1. There are also a wide variety of other oxides of the transition and rare earth metals with different valences that may be used, both individually and as more complex compounds. In each case, the mobile dopant can be an oxygen vacancy or an aliovalent element doped into the active region 102. The oxygen vacancies effectively act as dopants with one shallow and one deep energy level. Because even a relatively minor nonstoichiometry of about 0.1% oxygen vacancies in TiO₂₋ₓ is approximately equivalent to 5×10¹⁹ dopants/cm³, modulating oxygen vacancy profiles have strong effect on electron transport.

In other embodiments, the active region 102 can be a sulfide or a selenide of the transition metals with some ionic bonding character, essentially the sulfide and selenide analogues of the oxides described above.

In other embodiments, the active region 102 can be a semiconducting nitride or a semiconducting halide. For example, semiconducting nitrides include AlN, GaN, ScN, YN, LaN, rare earth nitrides, and alloys of these compounds and more complex mixed metal nitrides, and semiconducting halides include CuCl, CuBr, and AgCl. The active region 102 can be a phosphide or an arsenide of various transition and rare earth metals. In all of these compounds, the mobile dopant can be an anion vacancy or an aliovalent element.

A variety of dopants can be used and are selected from a group consisting of hydrogen, alkali, and alkaline earth cations, transition metal cations, rare earth cations, oxygen anions or vacancies, chalcogenide anions or vacancies, nitrogen anions or vacancies, pnictide anions or vacancies, or halide anions or vacancies.

TABLE
Exemplary List of Doped, Undoped, and
Mobile Dopants Composing Compound Materials.

| Undoped | Doped | Mobile Dopant |
|---|---|---|
| TiO₂ | TiO₂₋ₓ | Oxygen vacancies |
| ZrO₂ | ZrO₂₋ₓ | Oxygen vacancies |
| HfO₂ | HfO₂₋ₓ | Oxygen vacancies |
| SrTiO₂ | SrTiO₂₋ₓ | Oxygen vacancies |
| GaN | GaN₁₋ₓ | Nitrogen vacancies |
| CuCl | CuCl₁₋ₓ | Chlorine vacancies |
| GaN | GaN:S | Sulfide ions |

In other embodiments, the active region 102 can also be composed of a wide variety of semiconductor materials including various combinations of direct and indirect semiconductors. A direct semiconductor is characterized by the valence band maximum and the conduction band minimum occurring at the same wavenumber. In contrast, indirect semiconductors are characterized by the valence band maximum and the conduction band minimum occurring at different wavenumbers. The indirect and direct semiconductors can be elemental and compound semiconductors. Indirect elemental semiconductors include Si and germanium (Ge), and compound semiconductors include III-V materials, where Roman numerals III and V represent elements in the IIIa and Va columns of the Periodic Table of the Elements. Compound semiconductors can be composed of column IIIa elements, such as aluminum (Al), gallium (Ga), and indium (In), in combination with column Va elements, such as nitrogen (N), phosphorus (P), arsenic (As), and antimony (Sb). Compound semiconductors can also be further classified according to the relative quantities of III and V elements. For example, binary semiconductor compounds include semiconductors with empirical formulas GaAs, InP, InAs, and GaP; ternary compound semiconductors include semiconductors with empirical formula GaAs_{y}P_{1-y}, where y ranges from greater than 0 to less than 1; and quaternary compound semiconductors include semiconductors with empirical formula InₓGa₁₋ₓAs_{y}P_{1-y}, where both x and y independently range from greater than 0 to less than 1. Other types of suitable compound semiconductors include II-VI materials, where II and VI represent elements in the IIb and VIa columns of the periodic table. For example, CdSe, ZnSe, ZnS, and ZnO are empirical formulas of exemplary binary II-VI compound semiconductors.

The dopants can be p-type impurities, which are atoms that introduce vacant electronic energy levels called “holes” to the electronic band gaps of the active region 102. These impurities are also called “electron acceptors.” The dopants can be n-type impurities, which are atoms that introduce filled electronic energy levels to the electronic band gap of the active region 102. These impurities are called “electron donors.” For example, boron (B), Al, and Ga are p-type impurities that introduce vacant electronic energy levels near the valence band of Si; and P, As, and Sb are n-type impurities that introduce filled electronic energy levels near the conduction band of Si. In III-V compound semiconductors, column VI impurities substitute for column V sites in the III-V lattice and serve as n-type impurities, and column II impurities substitute for column III atoms in the III-V lattice to form p-type impurities. Moderate doping of the active region 102 can have impurity concentrations in excess of about 10¹⁵ impurities/cm³ while more heavy doping of the active region 102 can have impurity concentrations in excess of about 10¹⁹ impurities/cm³.

### IV. Nanowire Implementations

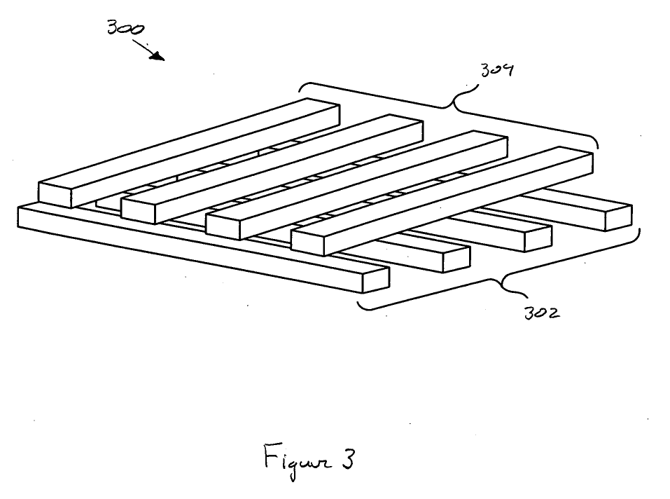

The switch 100 can be implemented at nanowire intersections of nanowire crossbar arrays. FIG. 3 shows an isometric view of a nanowire crossbar array 300 configured in accordance with embodiments of the present invention. The crossbar array 300 is composed of a first layer of approximately parallel nanowires 302 that are overlain by a second layer of approximately parallel nanowires 304. The nanowires of the second layer 304 are roughly perpendicular, in orientation, to the nanowires of the first layer 302, although the orientation angle between the layers may vary. The two layers of nanowires form a lattice, or crossbar, each nanowire of the second layer 304 overlying all of the nanowires of the first layer 302 and coming into close contact with each nanowire of the first layer 302 at nanowire intersections that represent the closest contact between two nanowires.

Although individual nanowires in FIG. 3 are shown with rectangular cross sections, nanowires can also have square, circular, elliptical, or more complex cross sections. The nanowires may also have many different widths or diameters and aspect ratios or eccentricities. The term “nanowire crossbar” may refer to crossbars having one or more layers of sub-microscale wires, microscale wires, or wires with larger dimensions, in addition to nanowires.

The layers can be fabricated by mechanical nanoimprinting techniques. Alternatively, nanowires can be chemically synthesized and can be deposited as layers of approximately parallel nanowires in one or more processing steps, including Langmuir-Blodgett processes. Other alternative techniques for fabricating nanowires may also be employed. Thus, a two-layer nanowire crossbar comprising first and second layers, as shown in FIG. 3, can be manufactured by any of numerous relatively straightforward processes. Many different types of conductive and semi-conductive nanowires can be chemically synthesized from metallic and semiconductor substances, from combinations of these types of substances, and from other types of substances. A nanowire crossbar may be connected to microscale address-wire leads or other electronic leads, through a variety of different methods in order to incorporate the nanowires into electrical circuits. At nanowire intersections, nanoscale electronic components, such as resistors, and other familiar basic electronic components, can be fabricated to interconnect two overlapping nanowires. Any two nanowires connected by a switch is called a “crossbar junction.”

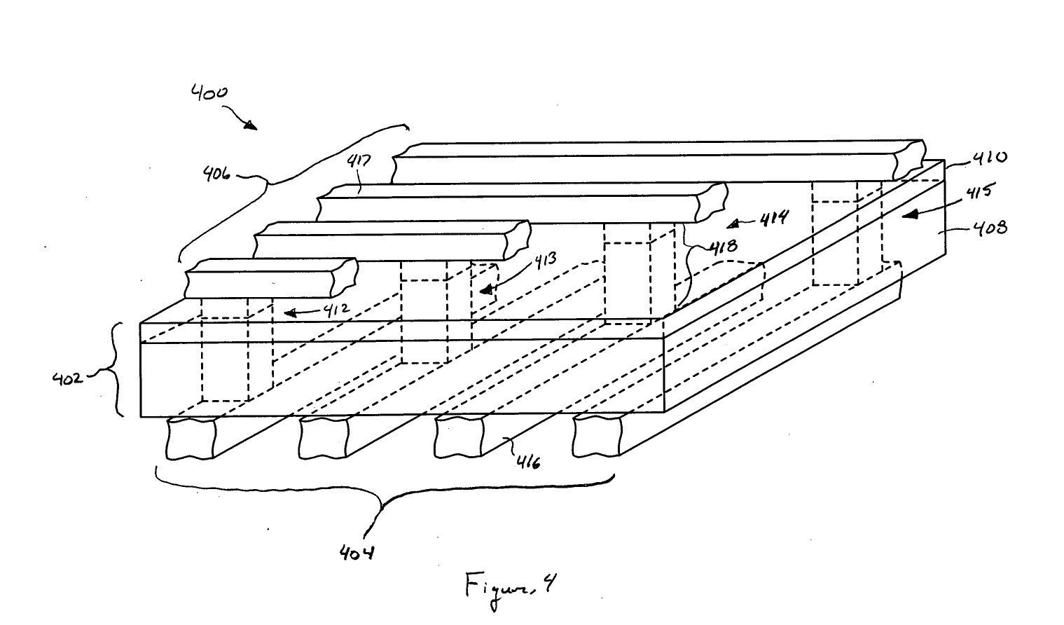

FIG. 4 shows an isometric view of a nanowire crossbar 400 revealing an intermediate layer 402 disposed between a first layer of approximately parallel nanowires 404 and a second layer of approximately parallel nanowires 406 in accordance with embodiments of the present invention. The layer 402 is composed of sub-layers 408 and 410. The sub-layer 408 can be composed of an undoped material, and the sub-layer 410 can be composed of a doped material, respectively. The material comprising the layer 402 and dopants are selected as described in subsection III to form switches 412-415 at each nanowire intersection. The nanowires can be composed of suitable metal of semiconductor materials and serve as electrodes. For example, sub-layer 408 can be composed of TiO₂, relatively thinner sub-layer 410 can be composed of TiO₂₋ₓ, where oxygen vacancies in the sub-layer 410 are dopants, and the nanowires can be composed of Pt. The switch 414 is formed by a nanowire 416 in the first layer 404, a nanowire 417 in the second layer 406, and a region 418 within the layer 402 between the nanowires 416 and 417. Each of the switches 412-415 can be operated separately to produce the forward, reverse, shunted, and head-to-head rectifiers described above with reference to FIG. 2.

### V. Examples

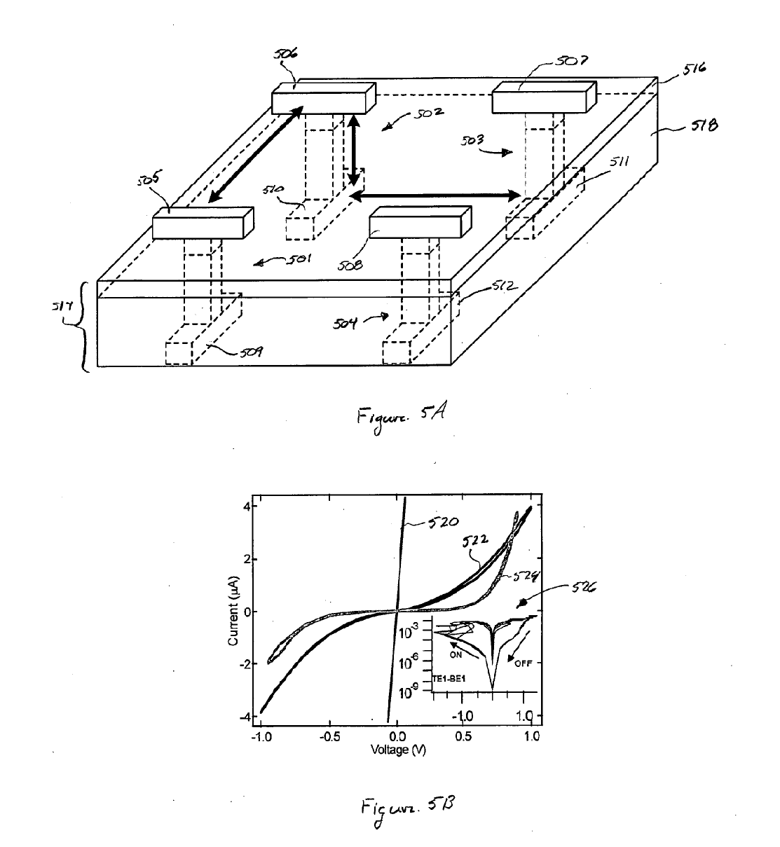

Oxygen vacancies in TiO₂ operate as n-type dopants transforming a wide band-gap oxide into a material that operates as an electrically conductive doped semiconductor. As described above with reference to FIG. 2, the dopant concentration at the two interfaces of the switch 100 play a crucial role in configuring the switch 100 to operate as one of the four rectifiers. FIG. 5A shows an isometric view of four separate switches 501-504 configured to demonstrate the role oxygen vacancies play in modulating the properties of the interfaces in accordance with embodiments of the present invention. Modulating the oxygen vacancies in turn controls the flow of electrons through a crossbar junction. The switching elements 501-504 of FIG. 5 consist of Pt first electrodes 505-508 and Pt second electrodes 509-512 separated vertically by a titanium dioxide layer 514. The first electrode pairs 505-506 and 507-508 are separated by approximately 1 mm, and the second electrode pairs 510-511 and 509-512 are also separated by approximately 1 mm. The titanium dioxide layer 514 is a bi-layer consisting of a thin, approximately 4 nm thick, TiO₂ layer 516 with few oxygen vacancies and a thicker, approximately 120 nm thick, TiO₂₋ₓ layer 518 with many more oxygen vacancies. The TiO₂₋ₓ layer is an n-type semiconductor with a carrier concentration of about 10¹⁹ cm⁻³ obtained from Hall measurement, and the TiO₂ layer is nearly stoichiometric.

Any pair of electrodes 505-512 form a switch, from which an I-V curve can be obtained, as shown in FIG. 5B. I-V curve 520 corresponds to second electrodes 510 and 511 and reveals two Ohmic-like barriers at the Pt/TiO₂₋ₓ interfaces. The fact that the resistance between electrodes 510 and 511 is low indicates that the bulk oxide is conductive. In contrast, I-V curve 522 corresponds to electron transmission between the two first electrodes 505 and 506 and is symmetric and nonlinear, revealing two Schottky-like barriers at the Pt/TiO₂ interfaces. Much lower current for the I-V curve 522 than that of the I-V curve 520 suggests that it is the Schottky-like interfaces that dominate the transmission of electrons through the switches since the bulk resistances are essentially the same for these two cases. A rectifying I-V curve 524 corresponds to electrodes 506 and 510 and is consistent with the fact that the corresponding device has a Schottky-like barrier at the Pt/TiO₂ interfaces and an Ohmic-like barrier at the Pt/TiO₂₋ₓ interfaces. One explanation as to why the current level between first and second electrodes 506 and 510 is lower than that of the first electrodes 505 and 506 is due to the much smaller effective junction surface area in the former case. An inset 526 in FIG. 5B is the log-scale I-V data showing reversible switching behavior of the switch formed between first and second electrodes 506 and 510.

The initial resistance state of the switches, i.e. the oxygen vacancy profile, in large degree determines the rectifying state of the switch. In practice, the oxygen vacancy profile can be controlled by engineering the structure and/or the fabrication condition of the active region, such as deposition gas species, annealing environment, inserting pure metal (e.g., Ti) at the interface. The following description provides results representing the realization of all three types of switching in real switches.

Circuit models accompanying the following experimental results include memristors. The term “memristor” is short for “memory resistor.” Memristors are a class of passive two-terminal circuit elements that maintain a functional relationship between the time integrals of current and voltage. This results in resistance varying according to the device's memristance function. Specifically engineered memristors provide controllable resistance useful for switching current. The memristor is a special case in so-called “memristive systems,” a class of mathematical models useful for certain empirically observed phenomena, such as the firing of neurons. The definition of the memristor is based solely on fundamental circuit variables, similar to the resistor, capacitor, and inductor. Unlike those more familiar elements, the necessarily nonlinear memristors may be described by any of a variety of time-varying functions. As a result, memristors do not belong to Linear Time-Independent circuit models. A linear time-invariant memristor is simply a conventional resistor.

The memristor is formally defined as a two-terminal element in which the magnetic flux Φₘ between the terminals is a function of the amount of electric charge q that has passed through the device. Each memristor is characterized by its memristance function describing the charge-dependent rate of change of flux with charge as follows:

$$M ( q ) = \frac{d {Φ}_{m}}{d q}$$

Based on Faraday's law of induction that magnetic flux Φₘ is the time integral of voltage, and charge q is the time integral of current, the memristance can be written as

$$M ( q ) = \frac{V}{I} .$$

Thus, the memristance is simply charge-dependent resistance. When M(q) is constant, the memristance reduces to Ohm's Law R=VII. When M(q) is not constant, the equation is not equivalent because q and M(q) vary with time. Solving for voltage as a function of time gives:

V(t)=M(q(t))I(t)

This equation reveals that memristance defines a linear relationship between current and voltage, as long as charge does not vary. However, nonzero current implies instantaneously varying charge. Alternating current may reveal the linear dependence in circuit operation by inducing a measurable voltage without net charge movement, as long as the maximum change in q does not cause change in M. Furthermore, the memristor is static when no current is applied. When I(t) and V(t) are 0, M(t) is constant. This is the essence of the memory effect.

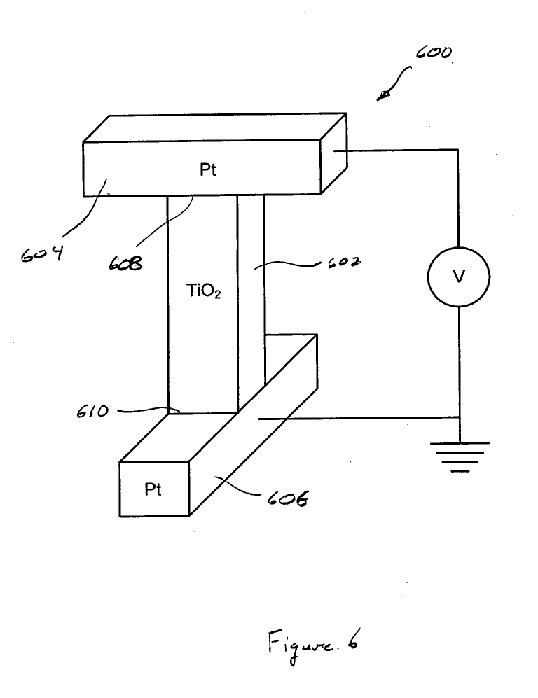

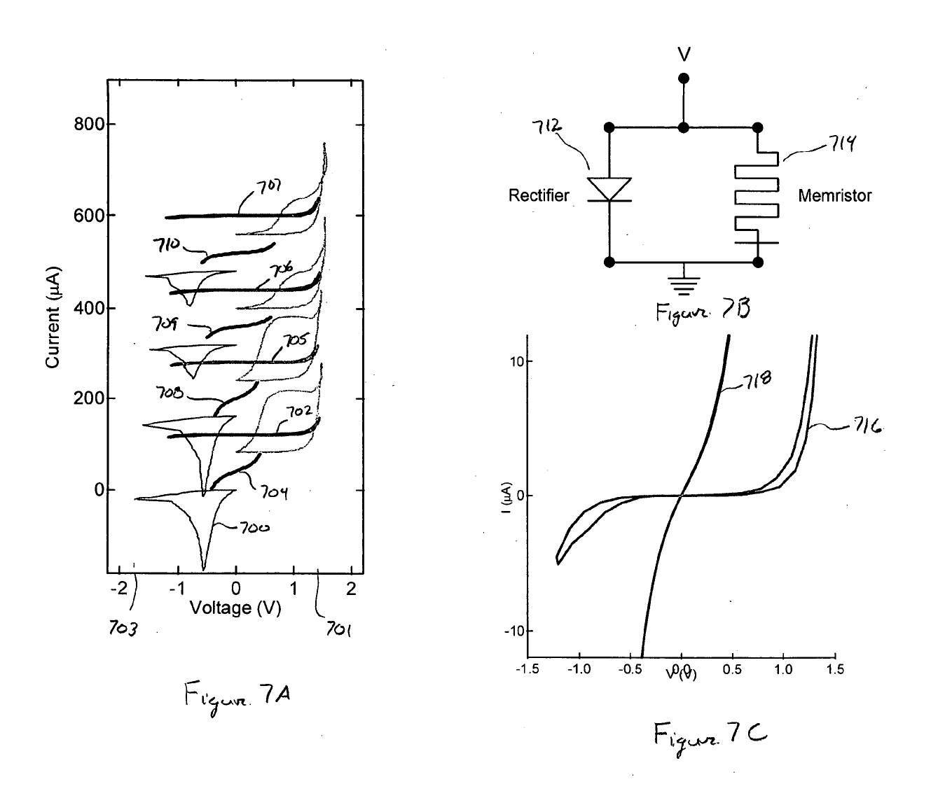

FIG. 6 shows an isometric view of a general representation of a switch 600 representing used to obtain the experimental results described below with reference to FIGS. 7-9 and is provided as a reference in describing the results presented in FIGS. 7-9. As shown in FIG. 6, the switch 600 comprises a TiO₂ active region 602 disposed between a crossing point of a Pt first electrode 604 and a Pt second electrode 606. The switch 600 was fabricated to have asymmetric oxygen vacancy concentrations at first interface 608 and second interface 610. In performing the electrical measurements, the second electrode 606 was grounded.

FIGS. 7-9 present experimental results corresponding to shunting, opening, and inverting switching in accordance with embodiments of the present invention for a Pt/TiO₂/Pt switch represented by the switch 600. In FIGS. 7-9, loops, such as loop 700 in FIG. 7A, represent negative and positive switching voltage sweeps. After each switching voltage sweep, a checking I-V was taken to measure the rectifying state of the device after switching.

FIGS. 7A-7C represent experimental results obtained from shunting switching an approximately 50×50 nm² Pt/TiO₂/Pt switch in accordance with embodiments of the present invention. The first interface 608 has fewer oxygen vacancies than the second interface 610, which remains Ohmic-like during switching. The active part is the first interface 608, which governs the electron transport of the switch 600. In FIG. 7A, a positive bias of about 1.4 V 701 applied to the first electrode 604 drives the oxygen vacancies from the first interface 608 toward the second interface 610 and switches the device “off.” The switch 600 in the “off” state is characterized by rectifying I-V curve 702, in FIG. 7A. A negative bias of approximately −1.8 V 703 applied to the first electrode 608 attracts the oxygen vacancies to the first interface 608, shunts the rectifier at the first interface 608, and switches the device to a higher conductance state characterized by I-V curve 704. Depending on the length and magnitude of the bias, the device can actually be switched to multiple “on” states represented by I-V curves 705-707 and multiple “off” states represented by I-V curves 708-710. Comparing with the first two “on” negative voltage sweeps, the last two “on” sweeps actually switch the device to a less conductive “on” states represented by I-V curves 709 and 710 in FIG. 7A.

FIG. 7B shows a circuit diagram representing the switching behavior of the switch during shunting switching in accordance with embodiments of the present invention. In the circuit diagram of FIG. 7B, a rectifier 712 is in parallel to a memristor 714, whose polarity is indicated by a bar on one end. A positive bias applied to the end of the memristor 714 with the bar switches the memristor 714 “on,” shunting the rectifier 712. An opposite bias switches the memristor 714 “off,” recovering the rectifier 712. The “on/off” conductance ratio is found to be about 10³ for both microscale and nanoscale devices, while the nanoscale devices can be operated at about 100 times a lower current level than that of the microscale devices.

FIG. 7C shows a plot of curves corresponding to shunting switching in accordance with embodiments of the present invention. I-V curve 716 corresponds to the switch in the “off” state, and I-V curve 718 corresponds to the switch in the “on” state.

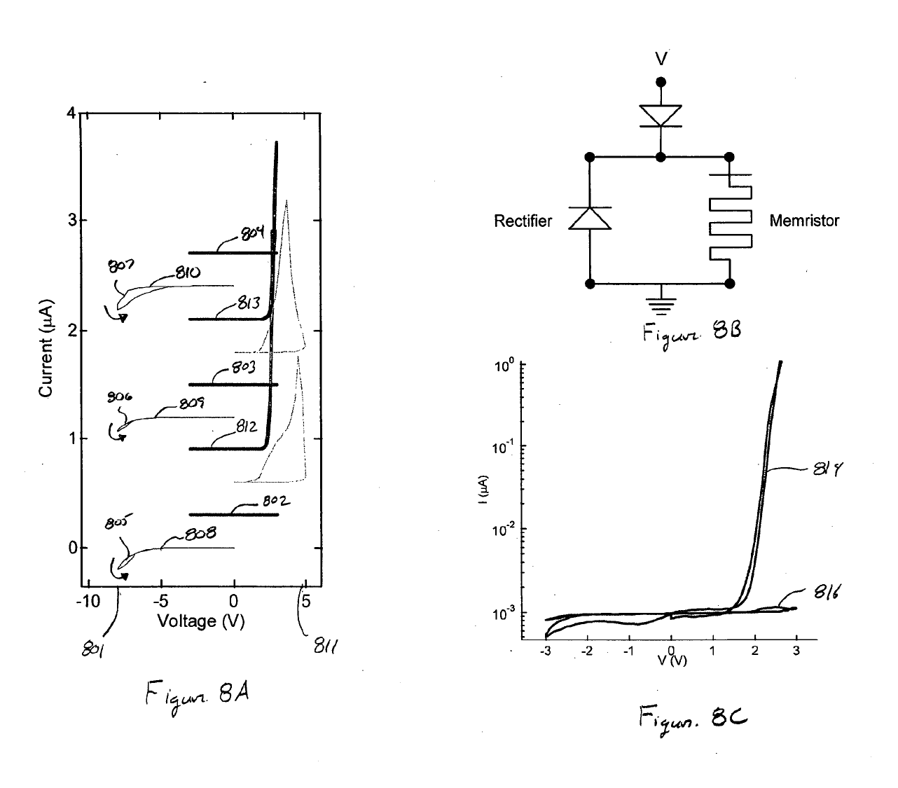

FIGS. 8A-8C represent experimental results obtained from opening switching of an approximately 5×5 μm² Pt/TiO₂/Pt switch in accordance with embodiments of the present invention. FIG. 8A shows a plot of the results for the opening switching. The two interfaces 608 and 610 have asymmetric dopant distribution. The more resistive first interface 608 (exposed to air for further oxidation before depositing the top electrode) remains Schottky-like or rectifying during switching and the active part is the second interface 610. A negative voltage bias of about −8 V 801 from the first electrode 604 to the second electrode 606 drives positively charged oxygen vacancies away from the second interface interface 610 and switches the device “off.” The I-V curves 802-804 reveal that the “off” state is resistive. There are small loops 805-807 with a counterclockwise directions in the “off” sweep curves 808-810, reflecting a tiny “on” switching for the first interface 608 during the greater “off” switching of the second interface 610. An opposite bias of about 5 V 811 switches the second interface 610 into an Ohmic-like barrier and the electrical transport of the device is limited only by the rectifying first interface 608, producing rectifying I-V curve 812 and 813 for the “on” state.

FIG. 8B shows a circuit diagram representing the switching behavior of the switch during opening switching in accordance with embodiments of the present invention. The equivalent circuit for this opening switching is similar to that for Shunting switching except that an intrinsic rectifier is added in series, which appears to be an efficient means for adding a diode to each crossbar intersection memory cell in order to limit cross talk in a memory architecture. In addition, the operating power is low for this type of device. A 10⁻⁹ A current level can be expected for nanoscale devices based on the 10⁻⁶ A current used to switch the micro-scale device in FIG. 4B and the scalability observed in this device. This type of switching also exhibits a high reproducibility.

FIG. 8C shows a plot of I-V curves corresponding to opening switching in accordance with embodiments of the present invention. A log-scale of the I-V curves for both “on” and “off” states are shown in FIG. 8C, exhibiting a roughly 10³ conductance ratio. I-V curve 814 corresponds to “on” state and I-V curve 816 corresponds to the “off” state.

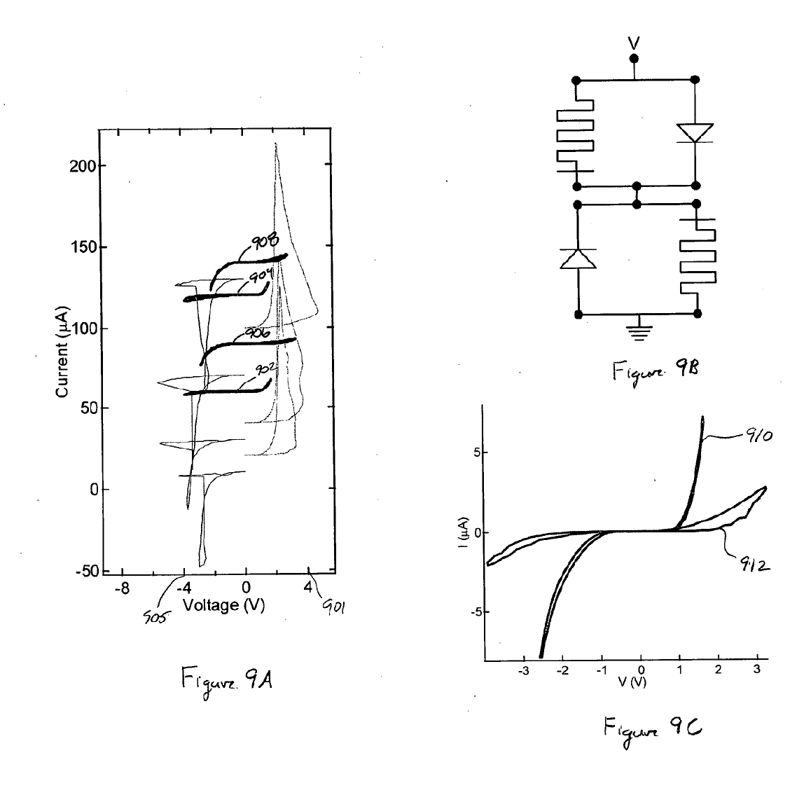

FIGS. 9A-9C represent experimental results obtained from inverting switching of an approximately 50×50 nm² Pt/TiO₂/Pt switch in accordance with embodiments of the present invention. FIG. 9A shows a plot of the results for the inverting switching. The distribution of oxygen vacancies within the active region 602 is symmetric and the oxygen vacancies changes at the two interfaces 608 and 610 takes place at approximately the same time but in opposite directions. When a positive bias about 4 V 901 is applied to the first electrode 604, oxygen vacancies are driven away from the first interface 608 and attracted to the second interface 610, resulting in more oxygen vacancies at the second interface 610 than at the first interface 608. The switch is switched to a rectifying state with a certain rectifying direction as shown by the checking I-V curves 902 and 904. Applying a negative bias of about −4 V 905 reverses the oxygen vacancy profile across the active region 602 and switches the switch to a resistive state with an opposite rectifying direction, which is represented by I-V curves 906 and 908.

FIG. 9B shows a circuit diagram representing the switching behavior of the switch during inverting switching in accordance with embodiments of the present invention. The circuit diagram reveals that inverting switching can be accomplished by including two head-to-head shunting switches in series, as shown in FIG. 7B.

FIG. 9C shows a plot of I-V curves corresponding to inverting switching in accordance with embodiments of the present invention. I-V curves 910 and 912 represent the forward and reverse rectifying states, respectively.

An oxygen vacancy is the only dopant used for the concept demonstration of the three the switching types described above. However, in principle, other dopants (e.g., C and N) with different properties, such as mobility, charge, and diffusivity, can be introduced to the system to intestinally build an asymmetric device. Only one dopant like oxygen vacancies can be sufficient for the inverting switch since the device is symmetric and equal but opposite changes at the two interfaces are needed for this type of switching. As for opening and shunting switching, one interface is heavily reduced for shunting or oxidized for opening in order to minimize the change at that interface during switching. A different dopant that is much less mobile than oxygen vacancies at the unchanged interface would serve that purpose even better.

The foregoing description, for purposes of explanation, used specific nomenclature to provide a thorough understanding of the invention. However, it will be apparent to one skilled in the art that the specific details are not required in order to practice the invention. The foregoing descriptions of specific embodiments of the present invention are presented for purposes of illustration and description. They are not intended to be exhaustive of or to limit the invention to the precise forms disclosed. Obviously, many modifications and variations are possible in view of the above teachings. The embodiments are shown and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents:

1. An electronic switch (100) comprising:
a first electrode (104);
a second electrode (106); and
an active region (102) disposed between the first electrode and the second electrode and including at least one dopant, wherein the switch can be re-configured to operate as a forward rectifier (112), a reverse rectifier (113), a head-to-head rectifier (114), or a shunted rectifier (115) by positioning the at least one dopant within the active region to control the flow of charge carriers through the switch.

2. The switch of claim 1 wherein the active region (102) further comprises:
at least one primary active region comprising at least one material for transporting the dopant that controls the flow of charge carriers through the switch; and
a secondary active region comprising at least one material for providing a source/sink of the dopant for the at least one primary active region.

3. The switch of claim 2 wherein the primary active region further comprises a material that is electronically semiconducting, nominally electronically insulating, or weakly ionic conducting.

4. The switch of claim 2 wherein the at least one primary active region further comprises a film having an electrical conductivity that is capable of being reversibly changed from a relatively low conductivity to a relatively high conductivity as a function of dopants being injecting into or out of the at least one primary active region via drift.

5. The switch of claim 2 wherein the at least one dopant of the secondary active region is selected to change the electrical conductivity of the at least one primary active region from a relatively low electrical conductivity to a relatively high electrical conductivity or from a relative high electrical conductivity to a relatively low conductivity.

6. The switch of claim 5 wherein the dopant is selected from a group consisting of ionized interstitial or substitutional impurity atoms, cation donor species, anion vacancies, and anionic acceptor species.

7. The switch of claim 6 wherein the dopant is selected from a group consisting of hydrogen, alkali and alkaline earth cations, transition metal cations, rare earth cations, oxygen anions or vacancies, chalcognenide anions or vacancies, nitrogen anions or vacancies, pnictide anions or vacancies, or halide anions or vacancies.

8. The switch of claim 1 wherein the at least one material for the primary active region and the material for the secondary active region are selected from the groups consisting of:
(1) oxides, sulfides, selenides, nitrides, phosphates, arsenides, and bromides of transition metals, rare earth metals, and alkaline earth metals;
(2) alloys of like compounds from list (1) with each other; and
(3) mixed compounds, in which there are at least two different metal atoms combined with at least one electronegative element.

9. The switch of claim 8 wherein the at least one material for the primary active region and the material for the secondary active region are selected from the group consisting of titanates, zirconates, hafnates, alloys of these three oxides in pairs or with all three present together, and compounds of the type ABO₃, where A represents at least one divalent element and B represents at least one of titanium, zirconium, and hafnium.

10. The switch of claim 8 wherein the at least one material for the primary active region and the material for the secondary active region are selected from the following list:
TiO₂/TiO₂₋ₓ;
ZrO₂/ZrO₂₋ₓ;
HfO₂/HfO₂₋ₓ;
SrTiO₂/SrTiO₂₋ₓ;
GaN/GaN₁₋ₓ;
CuCl/CuCl₁₋ₓ; and
GaN/GaN:S.

11. The switch of claim 1 wherein both electrodes are metal, metallic compounds, or one of the electrodes is metal and another of the electrodes is a semiconductor.

12. The switch of claim 1 wherein positioning the dopant within the active region further comprises applying a voltage of an appropriate magnitude and polarity that causes the dopant to drift into or away from particular regions of the active layer.

13. The switch of claim 1 wherein position the dopant near an electrode/active region interface makes the interface Ohmic-like and positioning the dopant away from an electrode/active region interface makes the interface Schottky-like.

14. A nanowire crossbar (300,400) comprising:
a first layer (302,404) of substantially parallel nanowires;
a second layer (304,406) substantially parallel nanowires overlaying the first layer of nanowires; and
at least one nanowire intersection (412-415) forming an electronic switch configured in accordance with claim 1.

15. The crossbar of claim 14 wherein any two nanowires in the first layer (505,506) form an electronic switch configured in accordance with claim 1 and any two nanowires in the second layer (510,511) form an electronic switch configured in accordance with claim 1.
